(19) United States
(12) Patent Application Publication
(10) Pub. No.: US 2022/0376103 A1
(43) Pub. Date: Nov. 24, 2022

(54) SEMICONDUCTOR DEVICE AND MANUFACTURING METHOD

(71) Applicant: FUJITSU LIMITED, Kawasaki-shi (JP)

(72) Inventor: Naoya OKAMOTO, Isehara (JP)

(73) Assignee: FUJITSU LIMITED, Kawasaki-shi (JP)

(21) Appl. No.: 17/577,754

(22) Filed: Jan. 18, 2022

(30) Foreign Application Priority Data
May 24, 2021 (JP) 2021-086833

(51) Int. Cl. H01L 29/778; H01L 29/66; H01L 29/06

(52) U.S. Cl. CPC H01L 29/7786; H01L 29/66431; H01L 29/0657

(57) ABSTRACT

A semiconductor device includes a substrate having a first surface and a second surface, the second surface being opposite to the first surface, the substrate having an opening formed from the first surface toward the second surface; a semiconductor device layer having a third surface facing the second surface; and a heat transfer member disposed in the opening, the heat transfer member being configured to transfer heat generated by the semiconductor device layer to the first surface, wherein the heat transfer member includes a diamond layer and a metal layer, the diamond layer covering a bottom surface and an inner wall surface of the opening, and the metal layer being disposed on the diamond layer.

### CROSS-REFERENCE TO RELATED APPLICATIONS

The present application is based upon and claims the benefit of priority from the prior Japanese Patent Application No. 2021-086833 filed on May 24, 2021, with the Japanese Patent Office, the entire contents of which are incorporated herein by reference.

### FIELD

The disclosures discussed herein are related to a semiconductor device and a manufacturing method.

### BACKGROUND

Nitride semiconductors such as GaN and AIN have properties, such as high saturation electron velocities, wide band gaps, or the like. Therefore, various studies have been conducted to apply the nitride semiconductors to high-voltage and high-power semiconductor devices by utilizing those properties. There have been many reports on field effect transistors as semiconductor devices using nitride semiconductors, especially high electron mobility transistors (HEMTs). Semiconductor devices using nitride semiconductors are expected to be used in, for example, millimeter-wave radar systems, wireless communication base station systems, server systems, and the like.

In general, the higher the output of the semiconductor device, the higher the amount of heat generated from the semiconductor device. Thus, in order to improve the heat dissipation efficiency, a heat dissipation structure including a diamond layer has been proposed.

### Related-Art Documents

### Patent Documents

[Patent Document 1] Japanese Patent Application Laid-Open No. 2020-027912

[Patent Document 2] Japanese Unexamined Patent Application Publication No. 2008-135532

[Patent Document 3] Publication No. 2016-528744

[Patent Document 4] Japanese Patent Application Laid-Open No. 2018-041785

### Non-Patent Documents

[Non-Patent Document 1] B. Poust et al., “Selective Growth of Diamond in Thermal Vias for GaN HEMTs”, 2013 IEEE Compound Semiconductor Integrated Circuit Symposium (CSICS)

[Non-Patent Document 2] J. D. Blevins et al., “Prospects for Gallium Nitride-on-Diamond Transistors”, 2016 IEEE Compound Semiconductor Integrated Circuit Symposium (CSICS)

### SUMMARY

According to one aspect of the present embodiments, a semiconductor device is provided. The semiconductor device includes

a substrate having a first surface and a second surface, the second surface being opposite to the first surface, the substrate having an opening formed from the first surface toward the second surface;

a semiconductor device layer having a third surface facing the second surface; and

a heat transfer member disposed in the opening, the heat transfer member being configured to transfer heat generated by the semiconductor device layer to the first surface, wherein the heat transfer member includes a diamond layer and a metal layer, the diamond layer covering a bottom surface and an inner wall surface of the opening, and the metal layer being disposed on the diamond layer.

The object and advantages of the embodiment will be realized and attained by means of the elements and combinations particularly pointed out in the claims. It is to be understood that both the foregoing general description and the following detailed description are exemplary and explanatory and are not restrictive of the invention, as claimed.

### BRIEF DESCRIPTION OF DRAWINGS

FIG. 1 is a top view illustrating a semiconductor device according to a first embodiment;

FIG. 2 is a bottom view illustrating the semiconductor device according to the first embodiment;

FIG. 3 is a cross-sectional view illustrating the semiconductor device according to the first embodiment;

FIG. 4 is a cross-sectional view illustrating an example of usage of the semiconductor device according to the first embodiment;

FIG. 5 is a cross-sectional view (Part 1) illustrating a method of manufacturing the semiconductor device according to the first embodiment;

FIG. 6 is a cross-sectional view (Part 2) illustrating the method of manufacturing the semiconductor device according to the first embodiment;

FIG. 7 is a cross-sectional view (Part 3) illustrating a method of manufacturing the semiconductor device according to the first embodiment;

FIG. 8 is a cross-sectional view (Part 4) illustrating a method of manufacturing the semiconductor device according to the first embodiment;

FIG. 9 is a cross-sectional view (Part 5) illustrating a method of manufacturing the semiconductor device according to the first embodiment;

FIG. 10 is a cross-sectional view (Part 6) illustrating a method of manufacturing the semiconductor device according to the first embodiment;

FIG. 11 is a cross-sectional view (Part 7) illustrating a method of manufacturing the semiconductor device according to the first embodiment;

FIG. 12 is a cross-sectional view (Part 8) illustrating a method of manufacturing the semiconductor device according to the first embodiment;

FIG. 13 is a cross-sectional view (Part 9) illustrating a method of manufacturing the semiconductor device according to the first embodiment;

FIG. 14 is a top view illustrating a semiconductor device according to a second embodiment;

FIG. 15 is a bottom view illustrating the semiconductor device according to the second embodiment;

FIG. 16 is a cross-sectional view illustrating the semiconductor device according to the second embodiment;

FIG. 17 is a cross-sectional view illustrating an example of usage of the semiconductor device according to the second embodiment;

FIG. 18 is a cross-sectional view (Part 1) illustrating a method of manufacturing the semiconductor device according to the second embodiment;

FIG. 19 is a cross-sectional view (Part 2) illustrating the method of manufacturing the semiconductor device according to the second embodiment;

FIG. 20 is a cross-sectional view (Part 3) illustrating the method of manufacturing the semiconductor device according to the second embodiment;

FIG. 21 is a cross-sectional view (Part 4) illustrating the method of manufacturing the semiconductor device according to the second embodiment;

FIG. 22 is a cross-sectional view (Part 5) illustrating the method of manufacturing the semiconductor device according to the second embodiment;

FIG. 23 is a diagram illustrating the results of a simulation of the heat dissipation efficiency;

FIG. 24 is a top view illustrating a semiconductor device according to a third embodiment;

FIG. 25 is a bottom view illustrating the semiconductor device according to the third embodiment;

FIG. 26 is a cross-sectional view illustrating the semiconductor device according to the third embodiment;

FIG. 27 is a cross-sectional view illustrating an example of usage of the semiconductor device according to the third embodiment;

FIG. 28 is a cross-sectional view (Part 1) illustrating a method of manufacturing the semiconductor device according to the third embodiment;

FIG. 29 is a cross-sectional view (Part 2) illustrating the method of manufacturing the semiconductor device according to the third embodiment;

FIG. 30 is a cross-sectional view (Part 3) illustrating the method of manufacturing the semiconductor device according to the third embodiment;

FIG. 31 is a cross-sectional view (Part 4) illustrating the method of manufacturing the semiconductor device according to the third embodiment;

FIG. 32 is a top view illustrating a semiconductor device according to a fourth embodiment;

FIG. 33 is a bottom view illustrating the semiconductor device according to the fourth embodiment;

FIG. 34 is a cross-sectional view illustrating the semiconductor device according to the fourth embodiment;

FIG. 35 is a cross-sectional view illustrating an example of usage of the semiconductor device according to the fourth embodiment;

FIG. 36 is a cross-sectional view (Part 1) illustrating a method of manufacturing the semiconductor device according to the fourth embodiment;

FIG. 37 is a cross-sectional view (Part 2) illustrating the method of manufacturing the semiconductor device according to the fourth embodiment;

FIG. 38 is a cross-sectional view (Part 3) illustrating the method of manufacturing the semiconductor device according to the fourth embodiment;

FIG. 39 is a cross-sectional view (Part 4) illustrating the method of manufacturing the semiconductor device according to the fourth embodiment;

FIG. 40 is a diagram illustrating a discrete package according to a fifth embodiment;

FIG. 41 is a circuit diagram illustrating a PFC circuit according to a sixth embodiment;

FIG. 42 is a circuit diagram illustrating a power supply device according to a seventh embodiment; and

FIG. 43 is a circuit diagram illustrating an amplifier according to an eighth embodiment.

### DESCRIPTION OF EMBODIMENTS

Although the heat dissipation efficiency can be improved by utilizing a diamond layer, it takes a considerable amount of time to form a diamond layer having a sufficient thickness in order to achieve a sufficient heat dissipation efficiency. This greatly increases a time required for manufacturing the semiconductor devices. For example, to form a diamond layer by a chemical vapor deposition (CVD) process, a deposition rate is approximately 0.5 μm per hour when the substrate temperature is 700° C. Therefore, it takes approximately 40 hours to form a diamond layer having a thickness of 20 μm.

Embodiments of the present disclosures are intended to provide a semiconductor device and a method of manufacturing a semiconductor device that is capable of exhibiting the excellent heat dissipation efficiency without forming a thick diamond layer.

Preferred embodiments of the present invention will be described with reference to the accompanying drawings. In the present specification and the drawings, constituent elements having substantially the same functions may be designated by the same reference numerals, and a repeated description thereof may be omitted.

(First Embodiment)

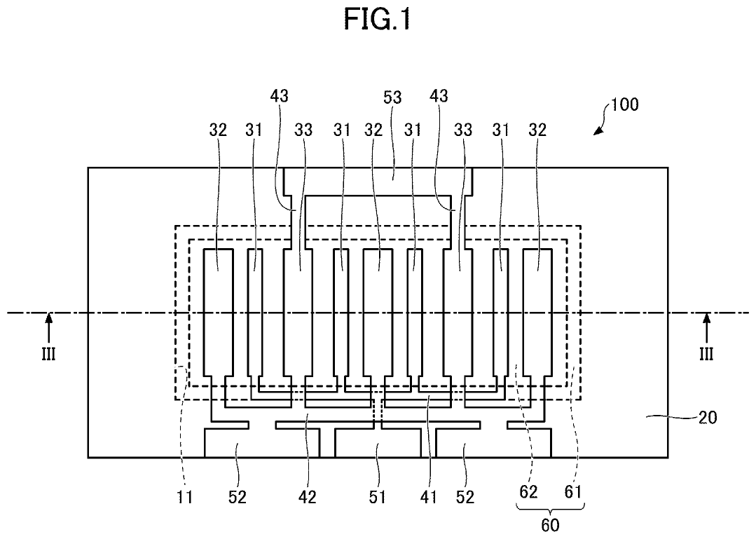

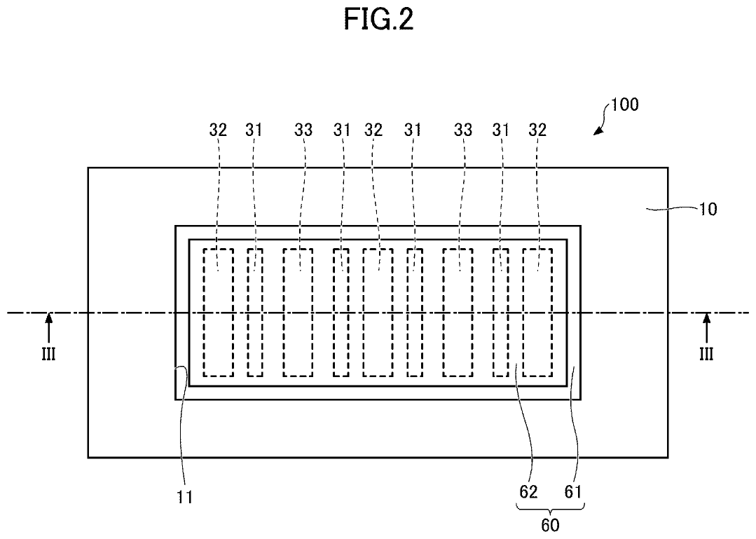

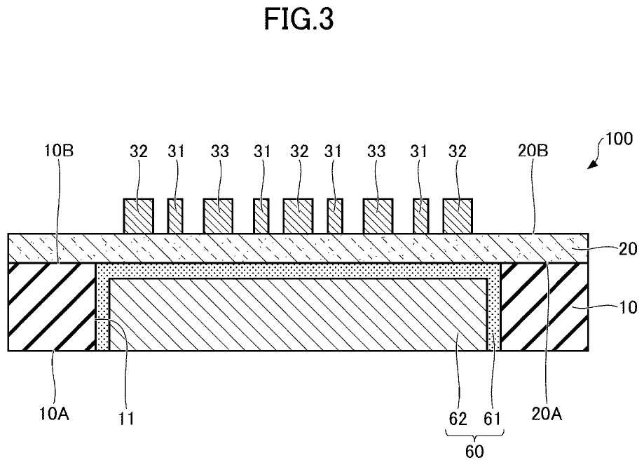

A first embodiment will be described first. The first embodiment relates to a semiconductor device having a high electron mobility transistor (HEMI). FIG. 1 is a top view illustrating a semiconductor device according to the first embodiment. FIG. 2 is a bottom view illustrating the semiconductor device according to the first embodiment. FIG. 3 is a cross-sectional view illustrating the semiconductor device according to the first embodiment. FIG. 3 corresponds to a cross-sectional view cut along a dash-dot line III-III in FIGS. 1 and 2.

The semiconductor device 100 according to the first embodiment includes a substrate 10, a semiconductor device layer 20, a plurality of gate electrodes 31, a plurality of source electrodes 32, and a plurality of drain electrodes 33, as illustrated in FIGS. 1 to 3.

The substrate 10 has a lower surface 10A and an upper surface 10B. The substrate 10 may be, for example, an AIN substrate, a SiC substrate, a GaN substrate, or a Si substrate. The thickness of the substrate 10 may be, for example, 20 μm to 100 μm, inclusive. The lower surface 10A is an example of a first surface, and the upper surface 10B is an example of a second surface.

The semiconductor device layer 20 has a lower surface 20A and an upper surface 20B. The semiconductor device layer 20 is, for example, an epitaxial layer. The lower surface 20A of the semiconductor device layer 20 faces the upper surface 10B of the substrate 10. The lower surface 20A may be in direct contact with the upper surface 10B. The semiconductor device layer 20 includes a plurality of compound semiconductor layers having a HEMT. The semiconductor device layer 20 includes, for example, a channel layer (electronic travel layer) such as GaN and a barrier layer (electronic supply layer) such as AlGaN. The semiconductor device layer 20 may further include a buffer layer, a spacer layer, a capping layer, and the like. The lower surface 20A is an example of the third surface, and the upper surface 20B is an example of the fourth surface.

The gate electrodes 31, the source electrodes 32 and the drain electrodes 33 are disposed on the upper surface 20B of the semiconductor device layer 20. The upper surface 20B further includes a gate trace 41, a gate pad 51, a source trace 42, source pads 52, drain traces 43, and a drain pad 53. The gate trace 41 electrically connects the plurality of gate electrodes 31 and the gate pad 51. The source trace 42 electrically connects the plurality of source electrodes 32 and the source pads 52. The drain traces 43 electrically connect a plurality of the drain electrodes 33 and a drain pad 53. In a plan view, the plurality of gate electrodes 31 and the gate trace 41 may be disposed in a comb-like configuration, the plurality of source electrodes 32 and the source trace 42 may be disposed in a comb-like configuration, and the plurality of drain electrodes 33 and the drain traces 43 may be disposed in a comb-like configuration.

An opening 11 is formed in the substrate 10 from the lower surface 10A toward the upper surface 10B. The opening 11 may extend to the upper surface 10B. That is, the opening 11 may penetrate the substrate 10. The opening 11 is formed, for example, in a rectangular shape in a plan view. In the semiconductor device layer 20, particularly in a plan view, heat is likely to be generated in portions between the gate electrodes 31 and the drain electrodes 33 that are disposed adjacent to each other. The opening 11 is preferably formed to surround portions between the gate electrodes 31 and drain electrodes 33 that are adjacent to each other in a plan view.

The semiconductor device 100 includes a thermal via 60 disposed in the opening 11 for transferring heat generated by the semiconductor device layer 20 to the lower surface 10A of substrate 10. The thermal via 60 includes a diamond layer 61 and a metal layer 62. The diamond layer 61 covers a bottom surface and inner wall surfaces of the opening 11. The diamond layer 61 may be in direct contact with the lower surface 20A of the semiconductor device layer 20. The thickness of the diamond layer 61 may be, for example, 5 μm to 10 μm, inclusive. The metal layer 62 includes, for example, Cu. Alternatively, the metal layer 62 may include Ag or the like. The opening 11 may be filled with a metal layer 62 from the inner portion of the diamond layer 61. The thermal via 60 is an example of a heat transfer member.

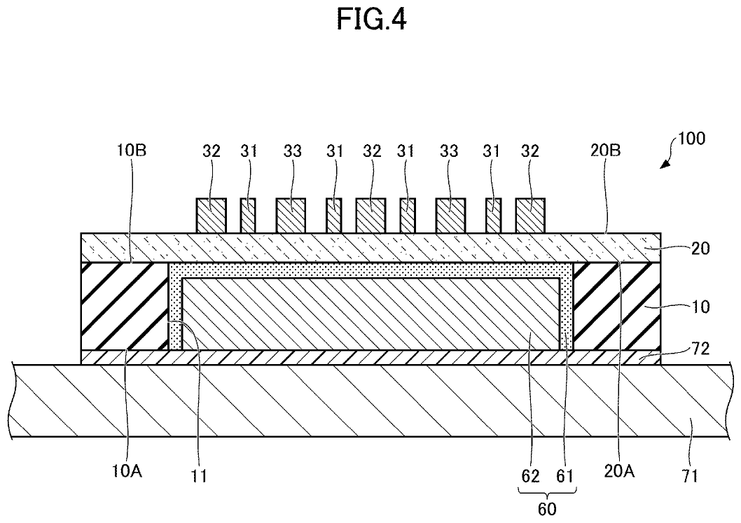

The semiconductor device 100 is implemented, for example, in a heat sink. FIG. 4 is a cross-sectional view illustrating an example of usage of the semiconductor device 100 according to the first embodiment. The semiconductor device 100 is implemented in a heat sink 71 using solder 72 as illustrated in FIG. 4. The material of the heat sink 71 is, for example, a CuMo alloy or a CuW alloy. The material of the solder 72 is, for example, AuSn alloy or the like. The solder 72 is in direct contact with the metal layer 62. The solder 72 may also be in direct contact with the diamond layer 61. The solder 72 thermally connects the heat sink 71 to the thermal via 60. The solder 72 is an example of a connecting member.

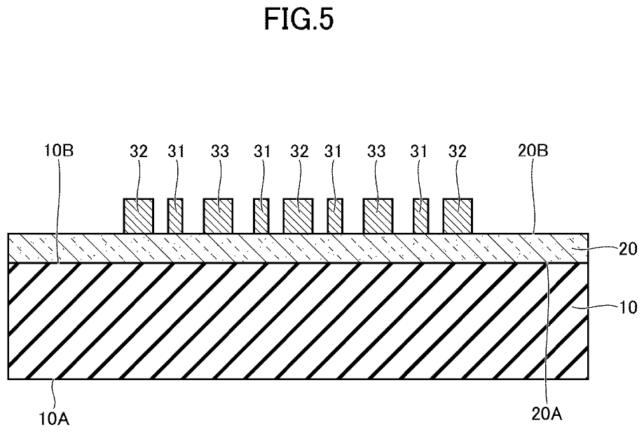

Next, a method of manufacturing the semiconductor device 100 according to the first embodiment will be described. FIGS. 5 to 13 are cross-sectional views illustrating a method of manufacturing the semiconductor device 100 according to the first embodiment.

First, as illustrated in FIG. 5, the substrate 10 is prepared to form a semiconductor device layer 20 on the upper surface 10B of the substrate 10. The semiconductor device layer 20 can be formed by a crystal growth process such as, for example, a metal-organic chemical vapor deposition (MOCVD) process. That is, the semiconductor device layer 20 can be formed by epitaxial growth. Next, the gate electrodes 31, the source electrodes 32 and the drain electrodes 33 are formed on the upper surface 20B of the semiconductor device layer 20. Although not illustrated in FIG. 5, the gate trace 41, the gate pad 51, the source trace 42, the source pads 52, the drain traces 43, and the drain pad 53 are also formed.

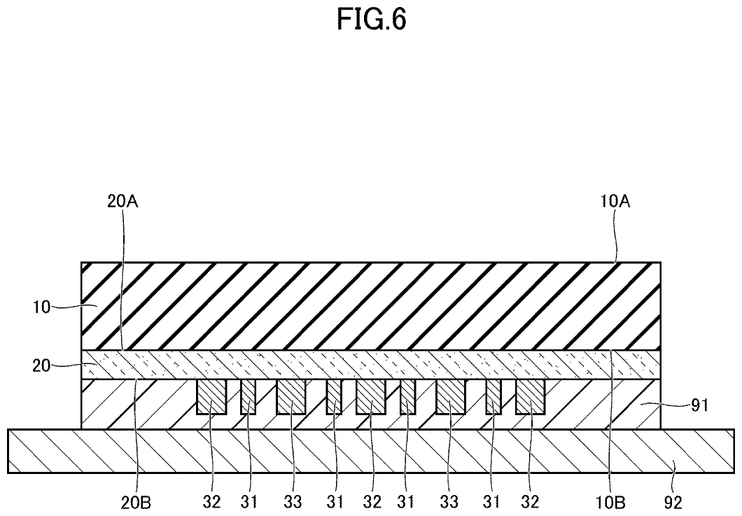

Subsequently, as illustrated in FIG. 6, an adhesive 91 is disposed on the upper surface 20B of the semiconductor device layer 20 which is attached to a support substrate 92. The adhesive 91 may be disposed, for example, by application.

Subsequently, the substrate 10 is ground from the lower surface 10A. The thickness of the substrate 10 after grounding is, for example, 20 μm to 100 μm, inclusive.

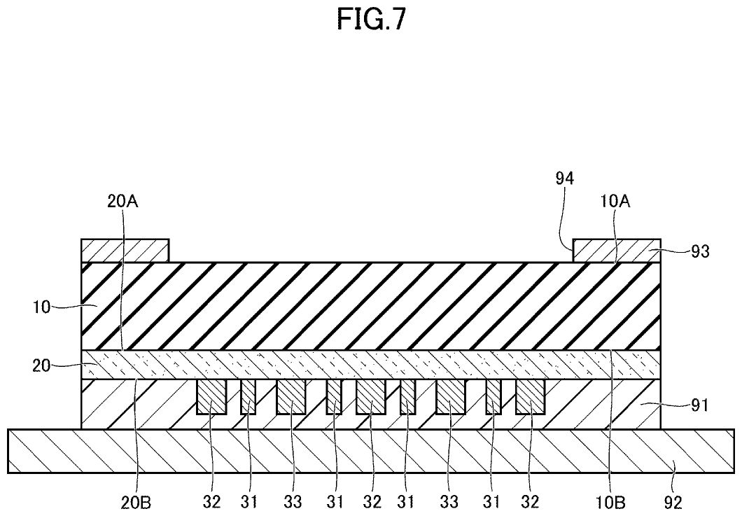

Then, as illustrated in FIG. 7, a metal mask 93 is formed on the lower surface 10A. The metal mask 93 has an opening 94 that exposes an area for forming the opening 11. The metal mask 93 has, for example, a Ni layer.

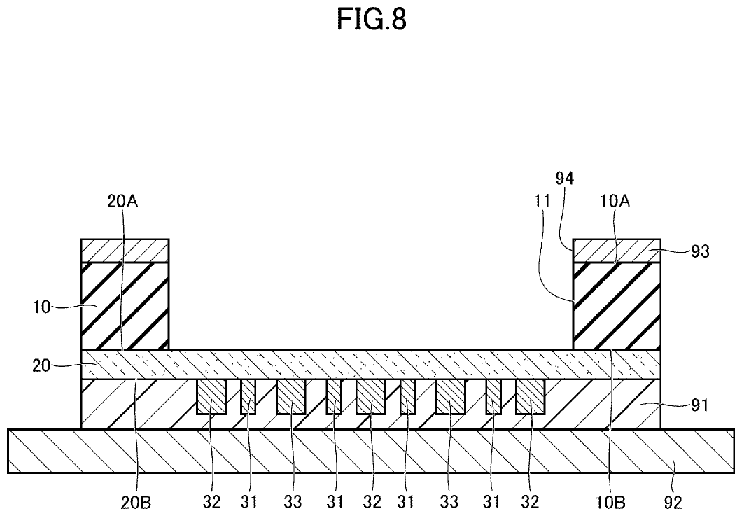

Thereafter, as illustrated in FIG. 8, the opening 11 is formed in the substrate 10 by dry etching a portion exposed from the opening 94 of the substrate 10. The opening 11 is formed such that the lower surface 20A of the semiconductor device layer 20 is exposed, for example. The opening 11 may be formed into the semiconductor device layer 20. The opening 11 may also be formed such that a portion of the substrate 10 remains in the thickness direction.

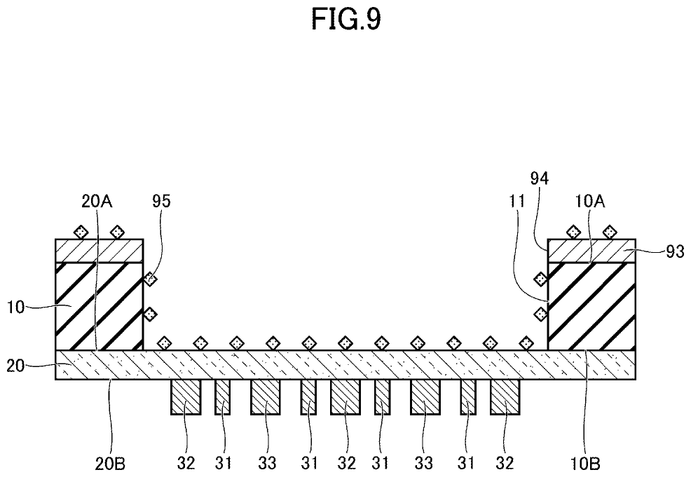

Subsequently, as illustrated in FIG. 9, the adhesive 91 is removed, and the substrate 10 and the semiconductor device layer 20 are separated from the support substrate 92. Nanodiamond grains 95 are then deposited over the inner wall surfaces of the opening 11, over the lower surface 20A of the semiconductor device layer 20, and over the lower surface of the metal mask 93.

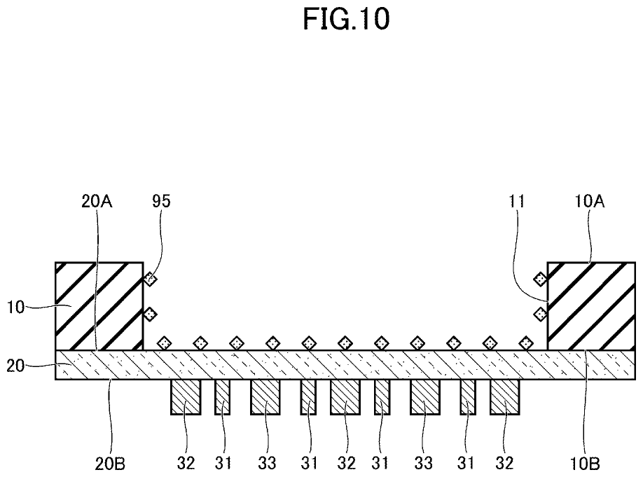

The metal mask 93 is then removed, as illustrated in FIG. 10. The metal mask 93 may be removed using, for example, dilute nitric acid. With removal of the metal mask 93, the nanodiamond grains 95 formed on the lower surface of the metal mask 93 are also removed.

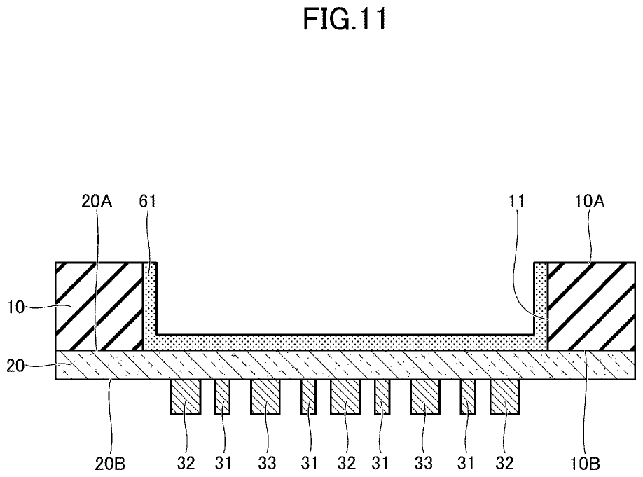

Then, as illustrated in FIG. 11, the nanodiamond grains 95 are used as growth nuclei to form a diamond layer 61 on the inner wall surfaces of the opening 11 and on the lower surface 20A of the semiconductor device layer 20. The nanodiamond grains 95 are incorporated into the diamond layer 61. The diamond layer 61 may be formed by, for example, a chemical vapor deposition (CVD) process. The thickness of the diamond layer 61 is, for example, 5 μm to 10 μm, inclusive. The growth rate of the diamond layer 61 is approximately 0.5 μm per hour when the temperature of the substrate 10 is 700° C.

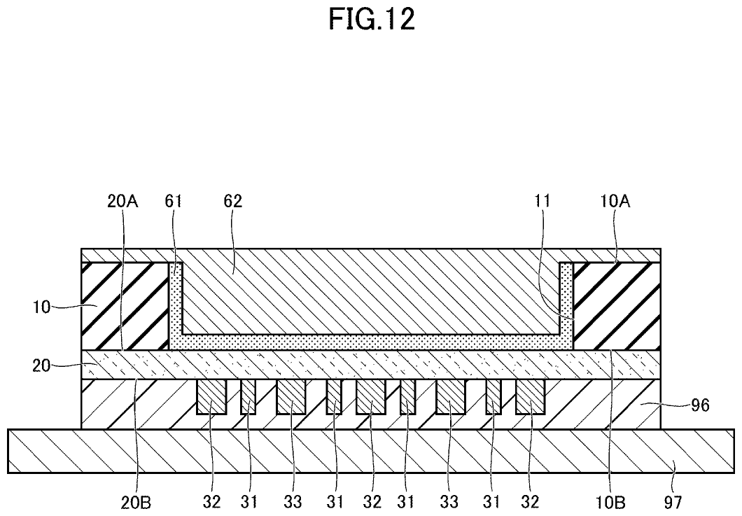

An adhesive 96 is then disposed on the upper surface 20B of the semiconductor device layer 20 which is attached to the support substrate 97, as illustrated in FIG. 12. The adhesive 96 may be disposed, for example, by application. The metal layer 62 is then formed over the lower surface of the diamond layer 61 and over the lower surface 10A of the substrate 10. In the formation of the metal layer 62, for example, a seed layer (not illustrated) is formed by sputtering, and a Cu plating layer is formed by electrolytic plating on the seed layer. The metal layer 62 is formed, for example, to fill an inner portion of the diamond layer 61 of the opening 11.

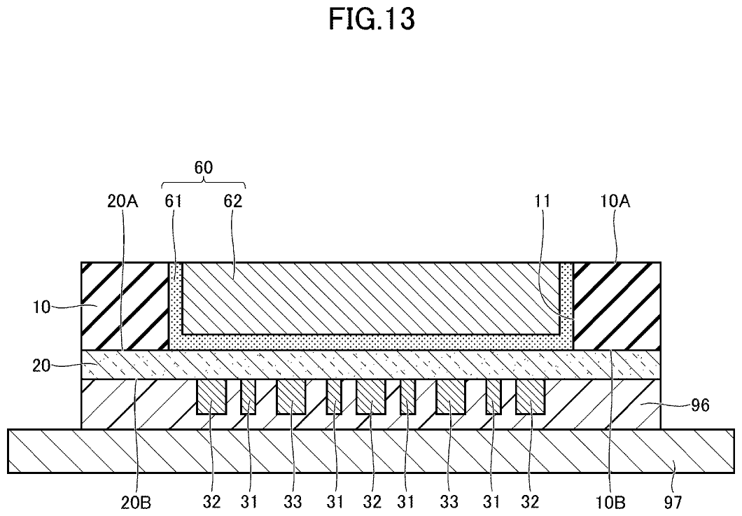

Subsequently, as illustrated in FIG. 13, the metal layer 62 is polished by the chemical mechanical polishing (CMP) process. The metal layer 62 may be polished until the lower surface 10A of the substrate 10 is exposed, or polishing of the metal layer 62 may be stopped before the lower surface 10A is exposed such that a portion of the metal layer 62 remains in the thickness direction. The adhesive 96 is then removed such that the substrate 10 and the semiconductor device layer 20 are separated from the support substrate 97 (see FIG. 3).

The semiconductor device 100 according to the first embodiment can be manufactured in this manner.

In the semiconductor device 100 according to the first embodiment, the semiconductor device layer 20 generates heat along with operation of the HEMT having a channel layer (an electron transit layer) and a barrier layer (an electron supply layer). As noted above, in the semiconductor device layer 20, heat is likely to be generated particularly in portions between the gate electrodes 31 and the drain electrodes 33 disposed adjacent to each other in a plan view.

In the semiconductor device 100, the thermal via 60 includes a diamond layer 61 and a metal layer 62, and heat generated in the semiconductor device layer 20 is propagated through the metal layer 62 and the diamond layer 61 to the heat sink 71 disposed on the lower surface 10A side.

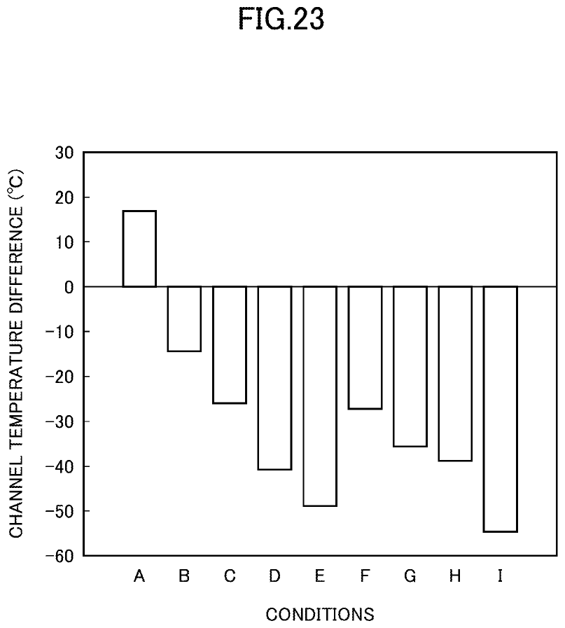

The heat propagated to the heat sink 71 is then dissipated outward from the heat sink 71. Thus, according to the first embodiment, excellent heat dissipation efficiency can be obtained even if the diamond layer 61 is not thick. For example, as illustrated in the results of the simulation described below (see FIG. 23), the first embodiment can exhibit the higher heat dissipation efficiency using the diamond layer 61 having a thickness of 5 μm can exhibit a heat dissipation efficiency higher than that of a reference example that uses the diamond layer having a thickness of 20 μm without forming the metal layer 62. This indicates that the heat dissipation efficiency in the first embodiment is better than that of the reference example, while the deposition time of the diamond layer in the first embodiment is reduced to ¼. If the deposition rate of the diamond layer is approximately 0.5 μm per hour, the deposition time of the diamond layer can be reduced by as much as 30 hours. Accordingly, the time required for the entire process can be greatly reduced even in consideration of the increased time required for forming the metal layer 62.

(Second Embodiment)

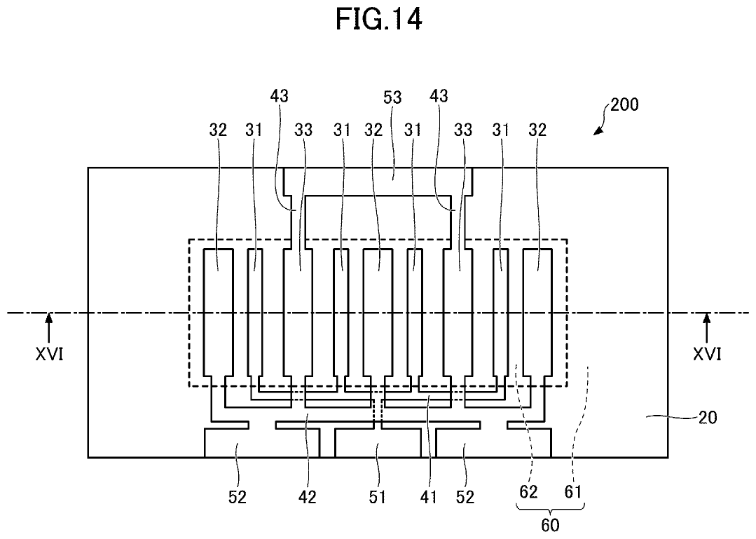

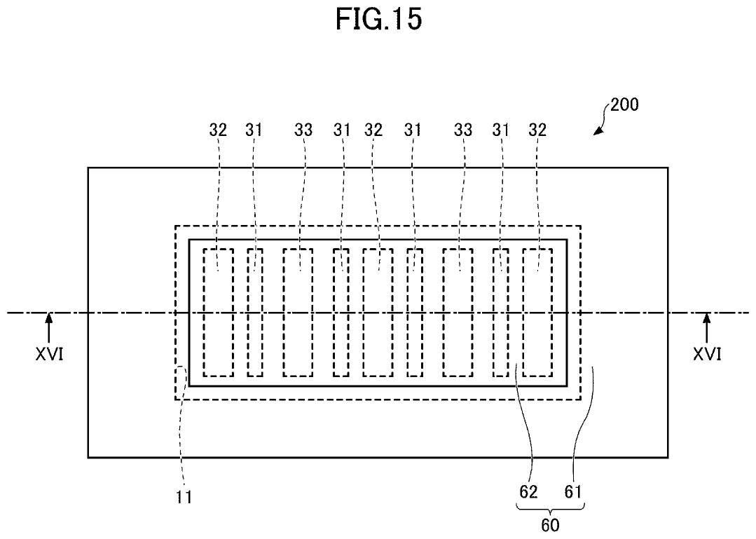

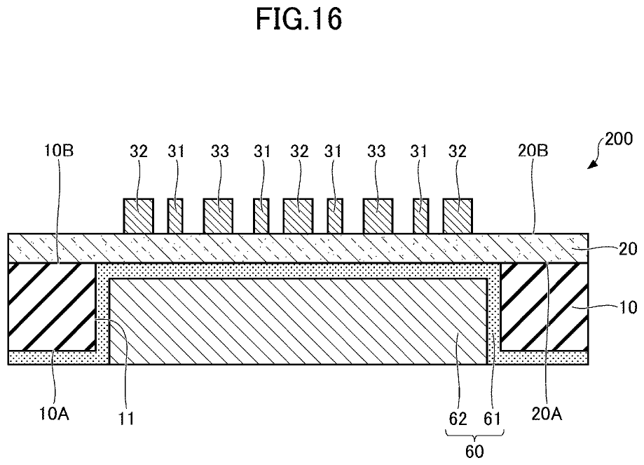

Next, a second embodiment will be described. The second embodiment is primarily different from the first embodiment in terms of the configuration of the thermal via 60. FIG. 14 is a top view illustrating a semiconductor device according to a second embodiment. FIG. 15 is a bottom view illustrating a semiconductor device according to a second embodiment. FIG. 16 is a cross-sectional view illustrating a semiconductor device according to a second embodiment. FIG. 16 corresponds to a cross-sectional view cut along an XVI-XVI line in FIGS. 14 and 15.

In the semiconductor device 200 according to the second embodiment, the diamond layer 61 contained in the thermal via 60 covers the bottom and inner wall surfaces of the opening 11 and further covers the lower surface 10A of the substrate 10, as illustrated in FIGS. 14 to 16. The lower surface of the metal layer 62 is flush with a lower surface of a portion, of the diamond layer 61, covering the lower surface 10A of the substrate 10.

Other configurations are substantially the same as those of the first embodiment.

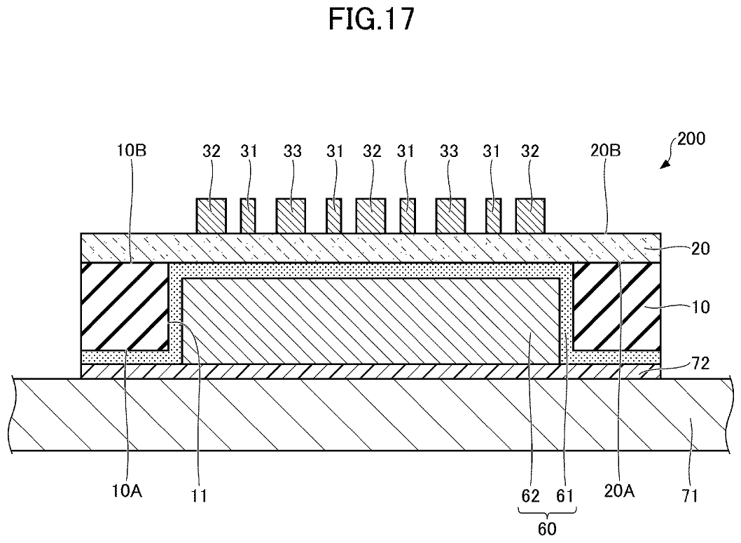

The semiconductor device 200 is also used, for example, by being disposed on a heat sink. FIG. 17 is a cross-sectional view illustrating an example of usage of the semiconductor device 200 according to the second embodiment. The semiconductor device 200 is disposed on the heat sink 71 using solder 72, as illustrated in FIG. 17. The solder 72 makes direct contact with the diamond layer 61 and the metal layer 62. The solder 72 thermally connects the heat sink 71 to the thermal via 60.

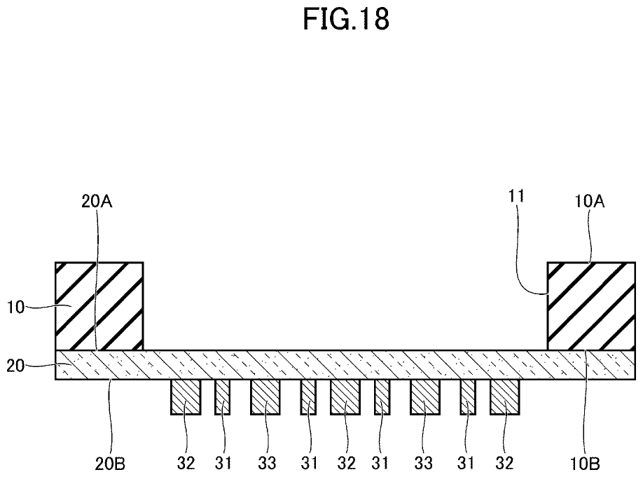

Next, a method of manufacturing the semiconductor device 200 according to the second embodiment will be described. FIGS. 18 to 22 are cross-sectional views illustrating the method of manufacturing the semiconductor device 200 according to the second embodiment.

First, the processes up to the formation of the opening 11 are performed in the same manner as in the first embodiment (see FIG. 8). The metal mask 93 is then removed, as illustrated in FIG. 18. The metal mask 93 can be removed using, for example, dilute nitric acid.

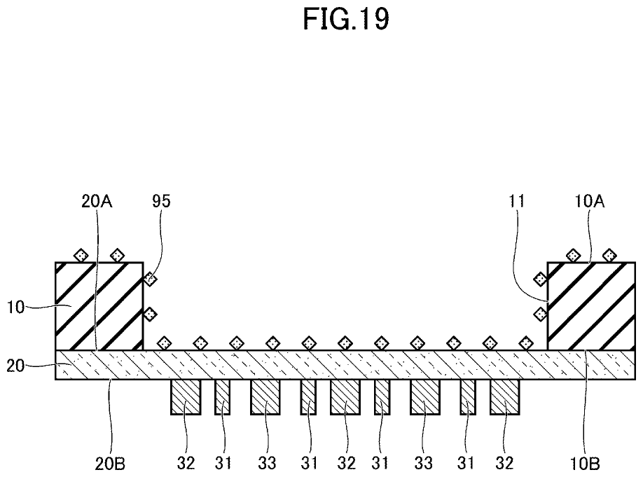

The nanodiamond grains 95 are then deposited over the inner wall surface of the opening 11, over the lower surface 20A of the semiconductor device layer 20, and over the lower surface 10A of the substrate 10, as illustrated in FIG. 19.

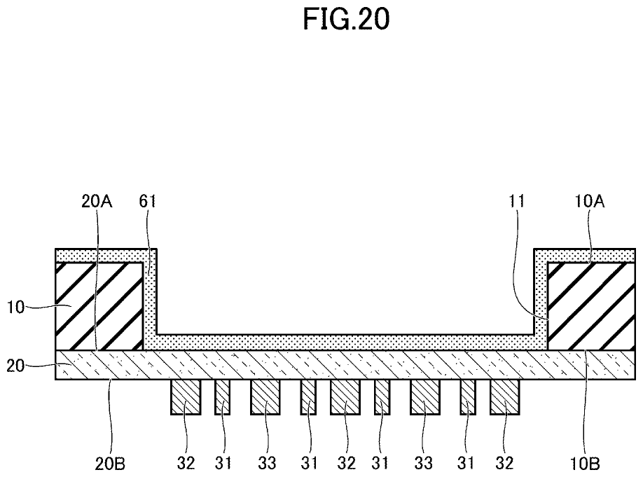

Subsequently, as illustrated in FIG. 20, the nanodiamond grains 95 are used to form the diamond layer 61 on the inner wall surface of the opening 11, on the lower surface 20A of the semiconductor device layer 20, and on the lower surface 10A of the substrate 10. The nanodiamond grains 95 are incorporated into the diamond layer 61.

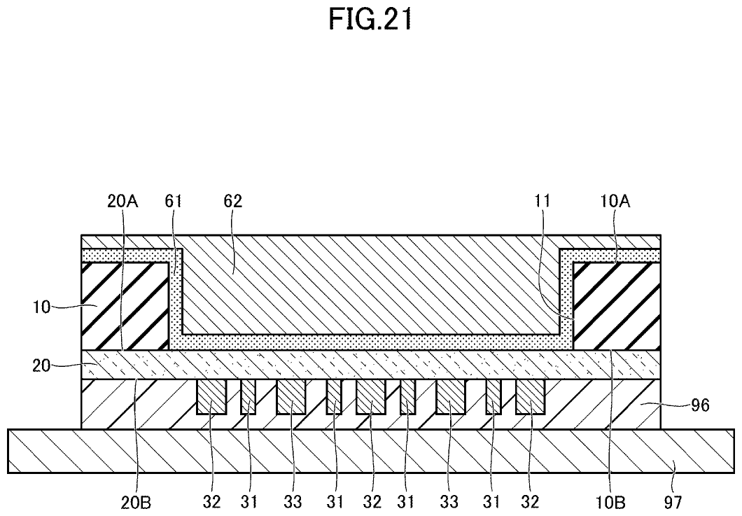

An adhesive 96 is then applied to the upper surface 20B of the semiconductor device layer 20 and to the support substrate 97, as illustrated in FIG. 21. The metal layer 62 is then formed over the lower surface of the diamond layer 61.

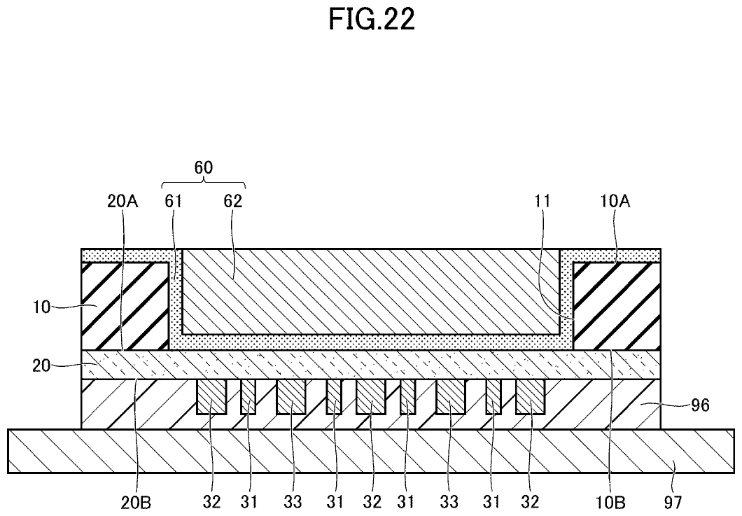

Subsequently, as illustrated in FIG. 22, the metal layer 62 is polished by the chemical mechanical polishing (CMP) process. The metal layer 62 may be polished until the bottom surface of the diamond layer 61 is exposed, or polishing of the metal layer 62 may be stopped before the bottom surface of the diamond layer 61 is exposed such that a portion of the metal layer 62 remains in the thickness direction. The adhesive 96 is then removed such that the substrate 10 and the semiconductor device layer 20 are separated from the support substrate 97 (see FIG. 16).

The semiconductor device 200 according to the second embodiment can be manufactured in this manner.

According to the second embodiment, the diamond layer 61 covers the lower surface 10A of the substrate 10. This can provide a better heat dissipation efficiency. For example, as illustrated in the results of the simulation described below (see FIG. 23), when compared to the reference example in which the metal layer 62 is not formed, the semiconductor device 200 according to the second embodiment using the diamond layer 61 having a thickness of 10 μm can exhibit a heat dissipation efficiency higher than that of the reference example using the diamond layer having a thickness of 50 μm. This indicates that the heat dissipation efficiency of the second embodiment is better than that of the reference example while the deposition time of the diamond layer of the second embodiment is reduced to ⅕. If the deposition rate of the diamond layer is approximately 0.5 μm per hour, the deposition time can be reduced by as much as 80 hours. Accordingly, the time required for the entire process can be greatly reduced even in view of the increased time required for forming the metal layer 62.

Herein, simulation relating to the heat dissipation efficiency performed in the first embodiment and the second embodiment will be described. In this simulation, the difference was calculated between the channel temperature at the time of operation of the HEMT in the first embodiment and the second embodiment and the channel temperature at the time of operation of the HEMT in the first reference example in which the opening 11 is not formed in the substrate 10 and the thermal via 60 is not disposed. In addition, the difference was also calculated between the channel temperature at the time of operation of the HEMT in the second reference example in which the diamond layer 61 is disposed but the metal layer 62 is not disposed and the channel temperature at the time of operation of the HEMT in the first reference example.

In any one of the first reference example, the second reference example, the first embodiment, and the second embodiment, the substrate 10 was an AIN substrate having a thickness of 50 μm. For the second reference example, the thickness of the diamond layer 61 was 10 μm (Condition A), 15 μm (Condition B), 20 μm (Condition C), 30 μm (Condition D), and 50 μm (Condition E). The condition E is a condition in which the opening is filled with a diamond layer 61. In the first embodiment, the thickness of the diamond layer 61 was 5 μm (Condition F) and 10 μm (Condition G). In the second embodiment, the thickness of the diamond layer 61 was 5 μm (condition H) and 10 μm (condition I). Other conditions are common between the first reference example, the second reference example, the first embodiment, and the second embodiment.

The results of the simulation are illustrated in FIG. 23. The vertical axis of the graph in FIG. 23 is the difference in the channel temperatures in the second reference example, the first embodiment, and the second embodiment relative to the channel temperature in the first reference example. A positive difference indicates a channel temperature higher than the channel temperature in the first reference example, and a negative difference indicates a channel temperature lower than the channel temperature in the first reference example.

As illustrated in FIG. 23, in the condition F of the first embodiment, even when the thickness of the diamond layer 61 is 5 μm, the channel temperature is lower than that of the condition C in the second reference example where the thickness of the diamond layer 61 is 20 μm. In the condition G of the first embodiment, the channel temperature further decreases. In the condition H of the second embodiment, even when the thickness of the diamond layer 61 is 5 μm, the channel temperature is lower than that of the condition G in the first embodiment where the thickness of the diamond layer 61 is 10 μm. In the condition I of the second embodiment, a channel temperature further decreases such that the channel temperature of the condition I of the second embodiment is lower than the channel temperature of the condition E of the second reference example where the thickness of the diamond layer 61 is 50 μm.

(Third Embodiment)

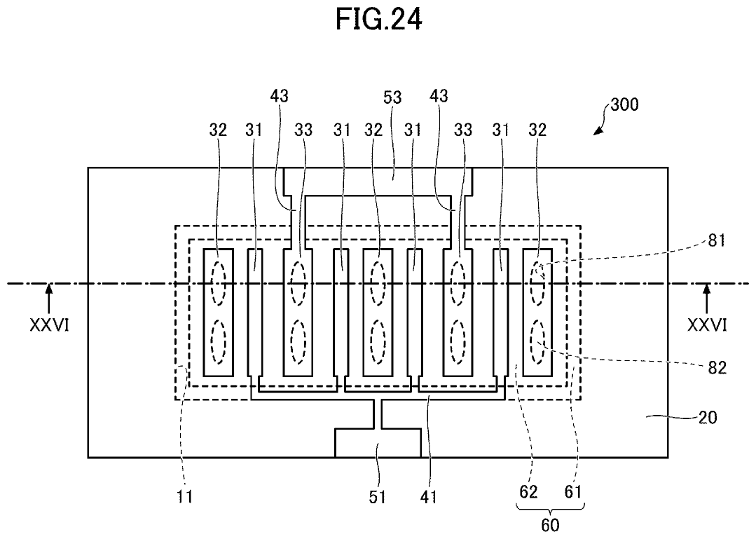

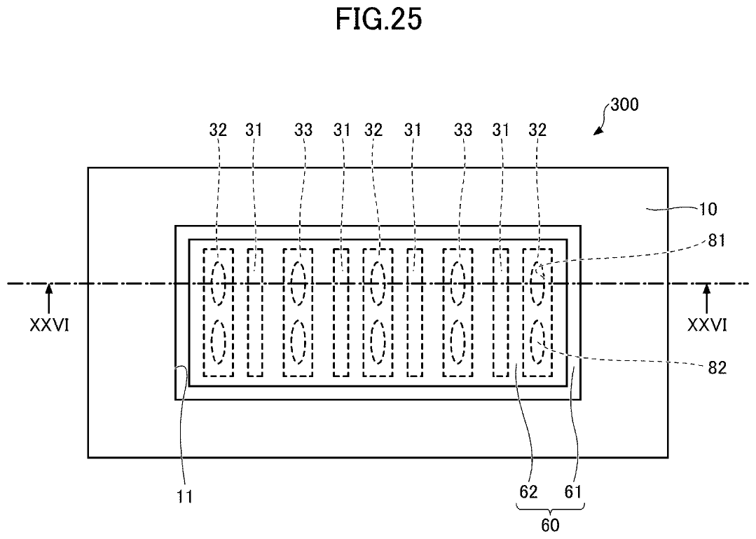

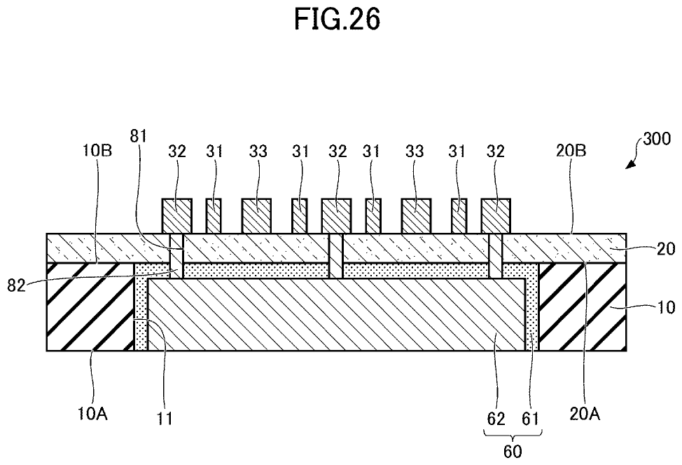

Next, a third embodiment will be described. The third embodiment differs from the first embodiment in that the source electrodes and the metal layer are electrically connected. FIG. 24 is a top view illustrating a semiconductor device according to the third embodiment. FIG. 25 is a bottom view illustrating the semiconductor device according to the third embodiment. FIG. 26 is a cross-sectional view illustrating the semiconductor device according to the third embodiment. FIG. 26 corresponds to a cross-sectional view cut along a XXVI-XXVI line in FIGS. 24 and 25.

In the semiconductor device 300 according to the third embodiment, through-holes 81 are formed in the semiconductor device layer 20 and the diamond layer 61 as illustrated in FIGS. 24 to 26. The through-holes 81 are formed between the source electrodes 32 and the metal layer 62. The semiconductor device 300 includes electrically conductive vias 82 disposed in through-holes 81 to electrically connect the source electrodes 32 and the metal layer 62. The electrically conductive vias 82 penetrate the semiconductor device layer 20 and the diamond layer 61. Conductive vias 82 contain, for example, Cu. The electrically conductive vias 82 may contain Ag. The source trace 42 and the source pads 52 need not be included in the semiconductor device 300.

Other configurations are substantially the same as those of the first embodiment.

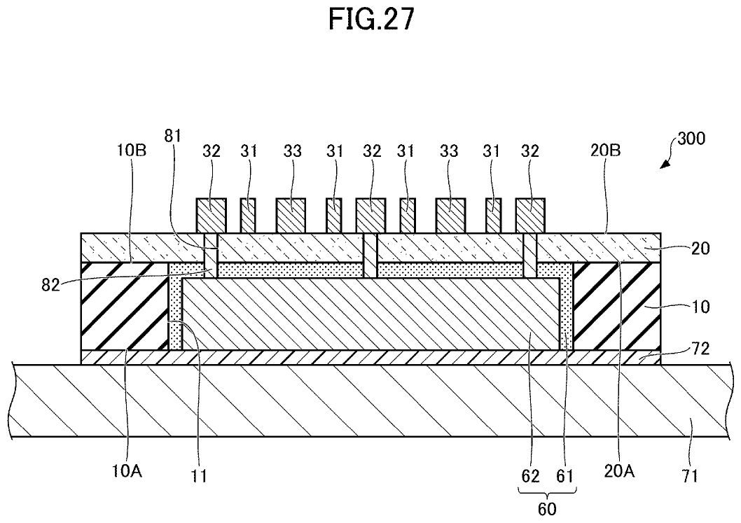

The semiconductor device 300 is also used, for example, by being disposed on a heat sink. FIG. 27 is a cross-sectional view illustrating an example of usage of the semiconductor device 300 according to the third embodiment. The semiconductor device 300 is disposed on the heat sink 71 using solder 72, as illustrated in FIG. 27. The solder 72 makes direct contact with the metal layer 62. The solder 72 may also be in direct contact with the diamond layer 61. The solder 72 thermally connects the heat sink 71 to the thermal via 60.

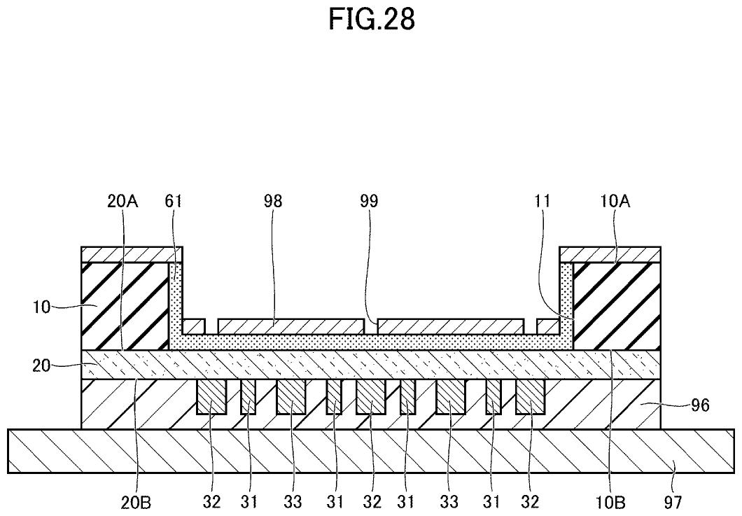

Next, a method of manufacturing the semiconductor device 300 according to the third embodiment will be described. FIGS. 28 to 31 are cross-sectional views illustrating the method of manufacturing the semiconductor device 300 according to the third embodiment.

First, the processes up to the formation of the diamond layer 61 are performed in the same manner as in the first embodiment (see FIG. 11). The adhesive 96 is then applied to the upper surface 20B of the semiconductor device layer 20 and also to the support substrate 97, as illustrated in FIG. 28. A metal mask 98 is then formed over the lower surface 10A of the substrate 10, and over the lower surface of the diamond layer 61. The metal mask 98 has openings 99 that exposes areas for forming the through-holes 81. The metal mask 98 includes, for example, a Ni layer. In the formation of the metal mask 98, for example, a seed layer (not illustrated) is formed by sputtering, areas where the through-holes 81 of the seed layer are to be formed are covered by photoresist or the like, and a Ni plating layer is formed on the seed layer by the electrolytic plating process. After forming of the Ni plating layer, the photoresist is removed, and portions exposed from the Ni plating layer of the seed layer are removed.

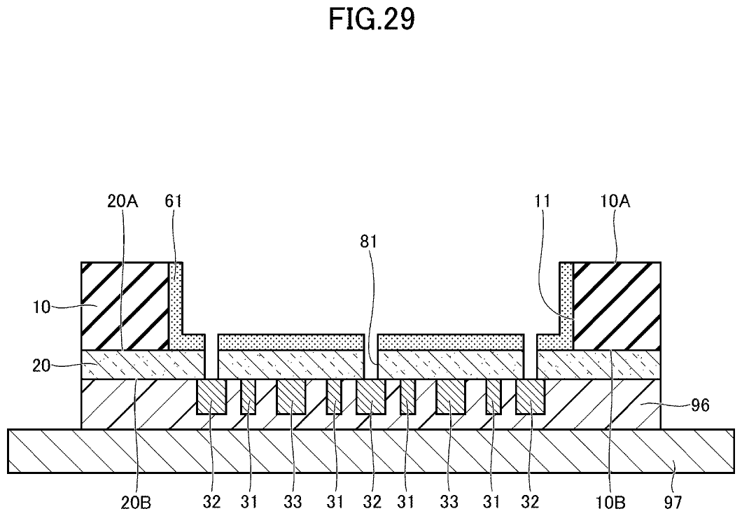

After forming of the metal mask 98, as illustrated in FIG. 29, dry etching of the portions exposed from the openings 99 of the diamond layer 61 is performed, and dry etching of the portions exposed from the openings 99 of the semiconductor device layer 20 is performed such that through-holes 81 are formed in the diamond layer 61 and in the semiconductor device layer 20. For example, the diamond layer 61 can be dry etched with oxygen, and the semiconductor device layer 20 can be dry etched with chlorine. The metal mask 98 is then removed. The metal mask 98 can be removed using, for example, dilute nitric acid.

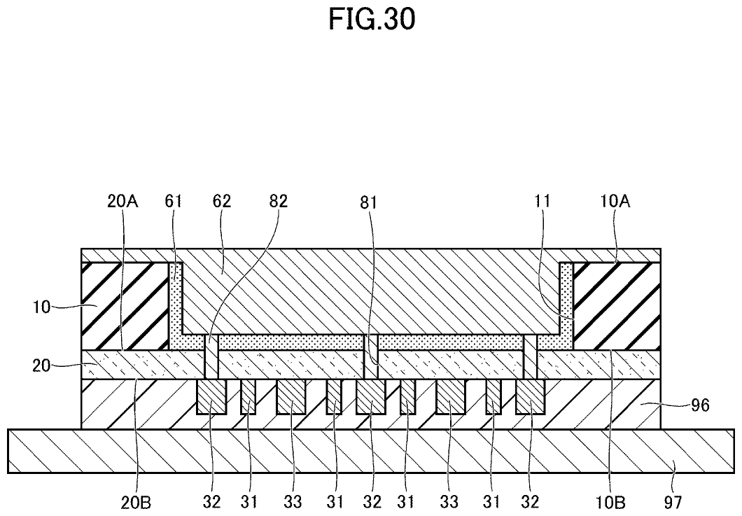

Thereafter, as illustrated in FIG. 30, a metal layer 62 is formed on the lower surface of the diamond layer 61 and also on the lower surface 10A of the substrate 10, and electrically conductive vias 82 are formed inside the through-holes 81. In the formation of the metal layer 62 and the electrically conductive vias 82, for example, a seed layer (not illustrated) is formed by sputtering, and a Cu plating layer is formed by electrolytic plating on the seed layer.

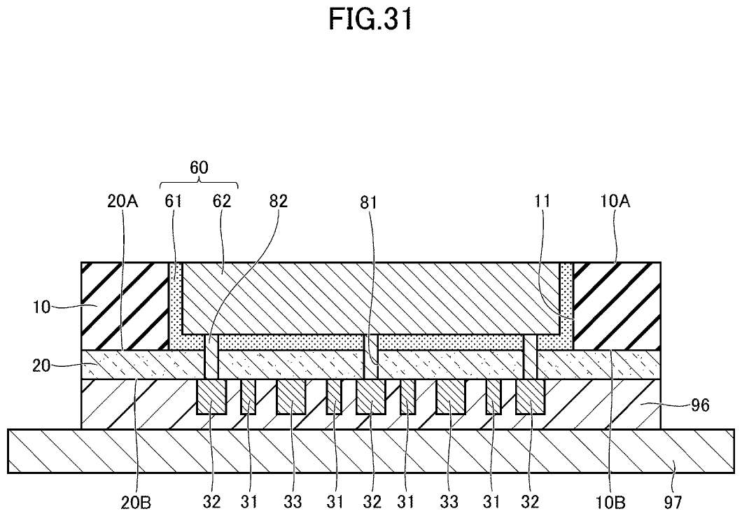

Subsequently, as illustrated in FIG. 31, the metal layer 62 is polished by the chemical mechanical polishing (CMP) process. The adhesive 96 is then removed such that the substrate 10 and the semiconductor device layer 20 are separated from the support substrate 97 (see FIG. 26).

In this manner, the semiconductor device 300 according to the third embodiment can be manufactured.

The third embodiment has the same effect as in the first embodiment. The source electrodes 32 are also electrically connected to the metal layer 62 through the electrically conductive vias 82. Thus, grounding of the metal layer 62 can reduce the source inductance.

(Fourth Embodiment)

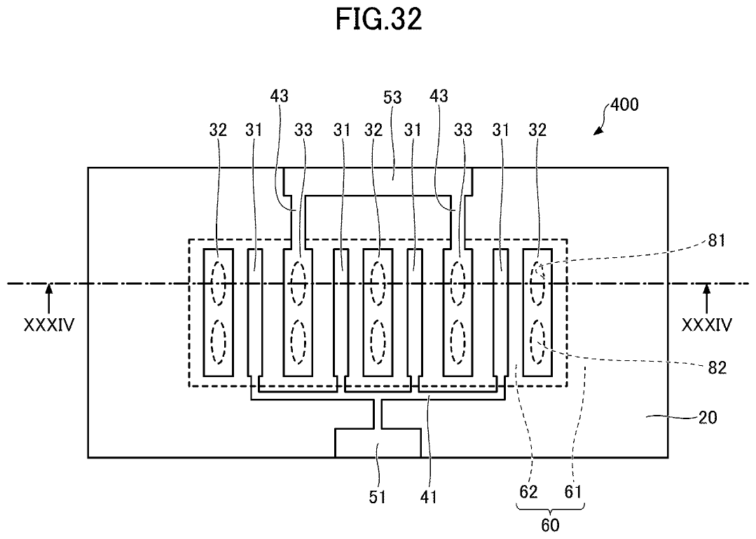

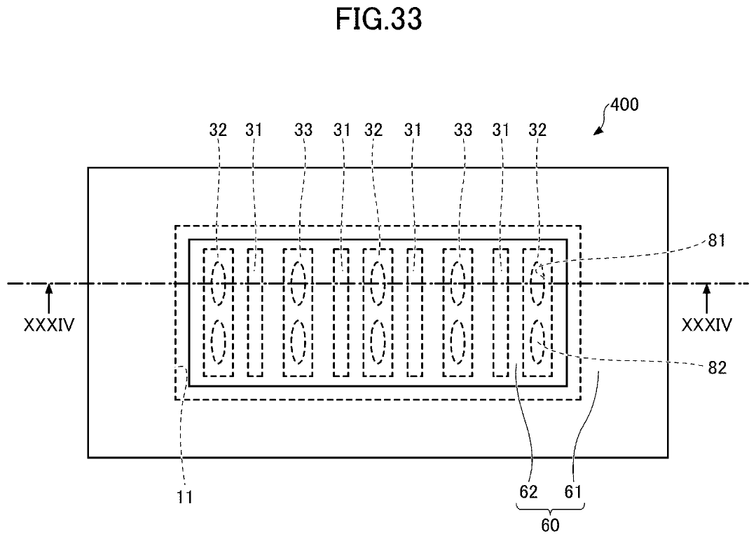

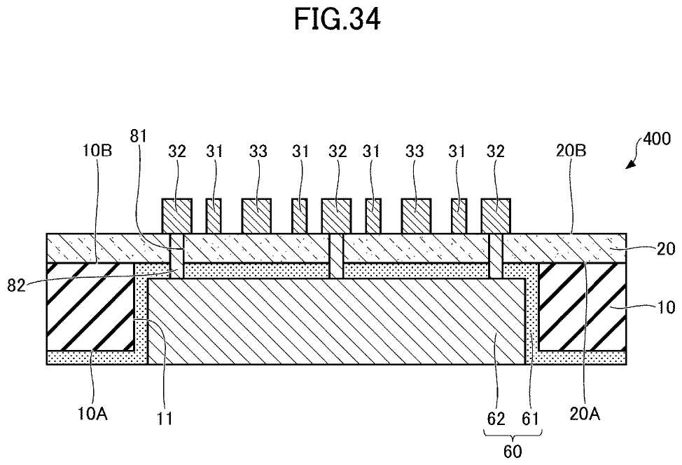

Next, a fourth embodiment will be described. The fourth embodiment differs primarily from the third embodiment in terms of the configuration of the thermal via 60. FIG. 32 is a top view illustrating a semiconductor device according to the fourth embodiment. FIG. 33 is a bottom view illustrating the semiconductor device according to the fourth embodiment. FIG. 34 is a cross-sectional view illustrating the semiconductor device according to the fourth embodiment. FIG. 34 corresponds to a cross-sectional view cut along a XXXIV-XXXIV line in FIGS. 32 and 33.

As in the second embodiment illustrated in

FIGS. 32 to 34, in the semiconductor device 400 according to the fourth embodiment, the diamond layer 61 included in the thermal via 60 covers a bottom surface and an inner wall surface of the opening 11, and further covers the lower surface 10A of the substrate 10. The lower surface of the metal layer 62 is flush with a lower surface of a portion, of the diamond layer 61, covering the lower surface 10A of the substrate 10.

Other configurations are substantially the same as those of the third embodiment.

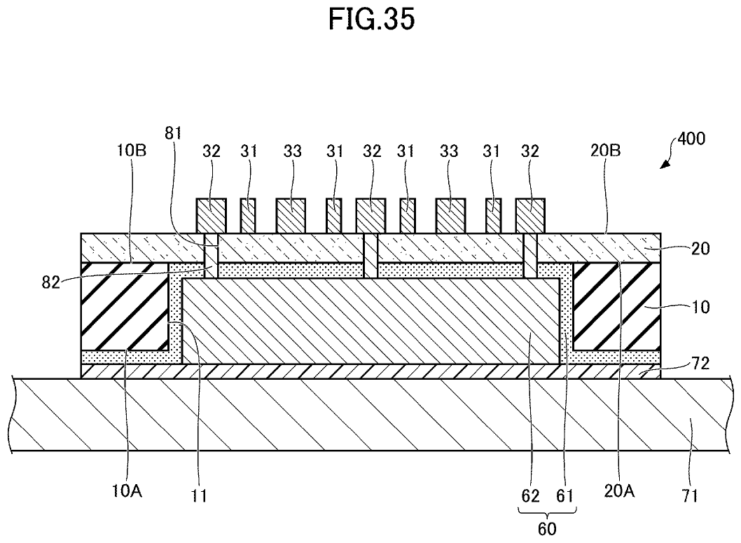

The semiconductor device 400 is also used, for example, by being installed in a heat sink. FIG. 35 is a cross-sectional view illustrating an example of usage of the semiconductor device 400 according to the fourth embodiment. The semiconductor device 400 is installed in a heat sink 71 using solder 72, as illustrated in FIG. 35. the solder 72 makes direct contact with the diamond layer 61 and the metal layer 62. The solder 72 thermally connects the heat sink 71 to the thermal via 60.

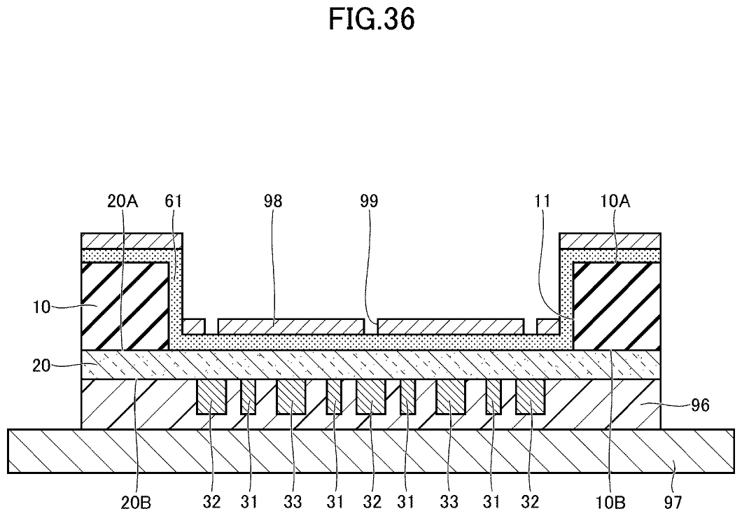

Next, a method of manufacturing the semiconductor device 400 according to the fourth embodiment will be described. FIGS. 36 to 39 are cross-sectional views illustrating a method of manufacturing the semiconductor device 400 according to the fourth embodiment.

First, the processes up to the formation of the diamond layer 61 are performed in the same manner as in the second embodiment (see FIG. 20). An adhesive 96 is then applied to the upper surface 20B of the semiconductor device layer 20 and also applied to the support substrate 97, as illustrated in FIG. 36. A metal mask 98 is then formed over the lower surface 10A of the substrate 10 and also over the lower surface of the diamond layer 61. The metal mask 98 has openings 99 that expose areas for forming the through-holes 81.

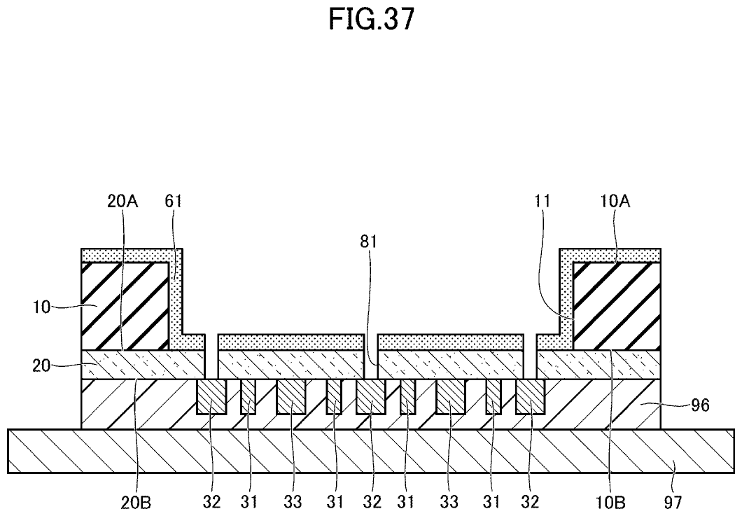

After forming of the metal mask 98, dry etching of the portions exposed from the openings 99 of the diamond layer 61 is performed, and dry etching of the portions exposed from the openings 99 of the semiconductor device layer 20 such that through-holes 81 are formed in the diamond layer 61 and also in the semiconductor device layer 20, as illustrated in FIG. 37. The metal mask 98 is then removed.

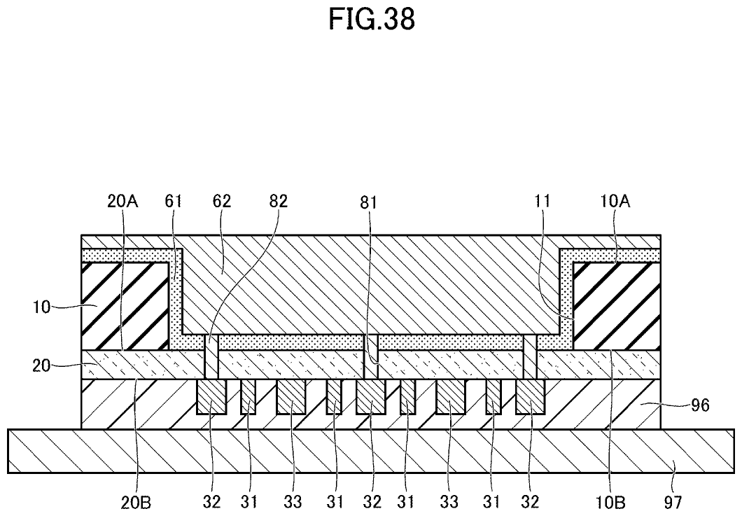

Thereafter, as illustrated in FIG. 38, a metal layer 62 is formed on the lower surface of the diamond layer 61, and electrically conductive vias 82 are formed inside the through-holes 81.

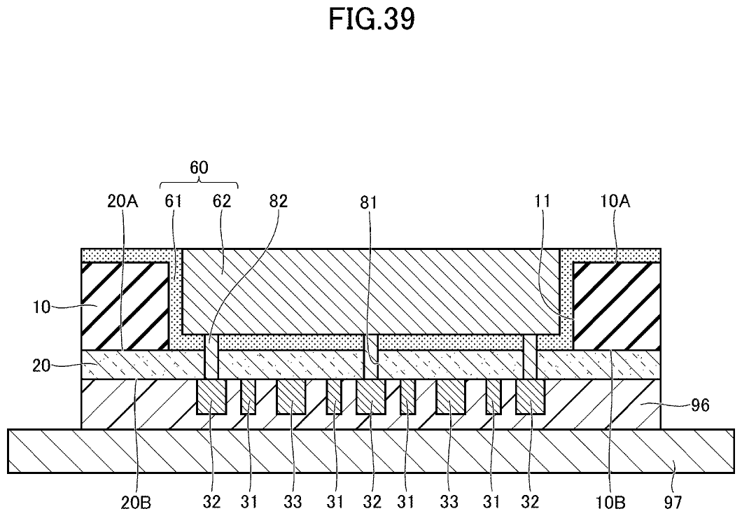

Subsequently, as illustrated in FIG. 39, the metal layer 62 is polished by the chemical mechanical polishing (CMP) process. The adhesive 96 is then removed such that the substrate 10 and the semiconductor device layer 20 are separated from the support substrate 97.

In this manner, the semiconductor device 400 according to the fourth embodiment can be manufactured.

The fourth embodiment has the same effect as the second embodiment. The source electrodes 32 are also electrically connected to the metal layer 62 via the electrically conductive vias 82. Thus, grounding of the metal layer 62 can reduce the source inductance.

In the third and fourth embodiments, the source trace 42 and the source pads 52 may have the electrically conductive vias 82 to connect the source pads 52 and the metal layer 62. In this case, grounding of the metal layer 62 can also reduce the source inductance.

The thickness of the substrate 10 is not particularly limited, but may be, for example, in a range of 20 μm to 100 μm, inclusive. If the substrate 10 is excessively thin, the parasitic capacitance between the semiconductor device formed in the semiconductor device layer 20 and the heat sink 71 or the like may be increased. If the substrate 10 is excessively thick, the heat dissipation efficiency may be reduced or forming of the opening 11 may take a longer time. For example, in the first and third embodiments, the thickness of the substrate 10 may be 30 μm to 100 μm, inclusive, and in the second and fourth embodiments, the thickness of the substrate 10 may be 20 μm to 70 μm, inclusive.

(Fifth embodiment)

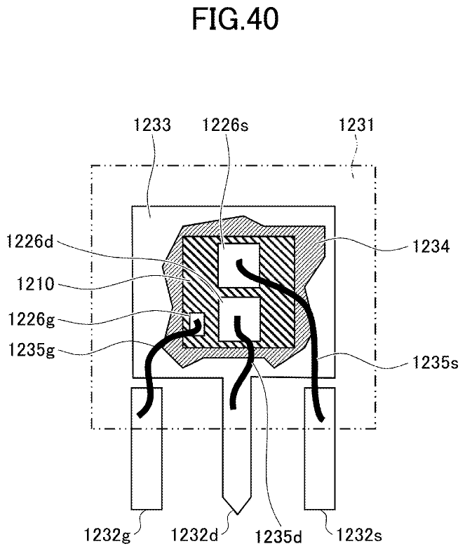

Next, a fifth embodiment will be described. The fifth embodiment relates to a discrete package of the HEMT. FIG. 40 is a diagram illustrating a discrete package according to a fifth embodiment.

In the fifth embodiment, as illustrated in FIG. 40, a back surface of a semiconductor device 1210 having a structure substantially the same as the structure of any one of the first to fourth embodiments is fixed to a land (die pad) 1233 using a die attach adhesive 1234, such as solder. One end of a wire 1235d, such as an Al wire or the like, is connected to a drain pad 1226d (the drain pad 53) which is connected to the drain electrode 33. The other end of the wire 1235d is connected to a drain lead 1232d which is integral with the land 1233. One end of a wire 1235s, such as an Al wire or the like, is connected to a source pad 1225s (the source pad 52) which is connected to the source electrode 32. The other end of the wire 1235s is connected to a source lead 1232s which is independent of the land 1233. One end of a wire 1235g, such as an Al wire or the like, is connected to a gate pad 1226g which is connected to the gate electrodes 31. When the semiconductor device 1210 has a structure substantially the same as the structure of the third or fourth embodiment, the metal layer 62 may be grounded. One end of a wire 1235g, such as an Al wire or the like, is connected to a gate pad 1226g (the gate pad 51) which is connected to the gate electrodes 31. The other end of the wire 1235g is connected to a gate lead 1232g which is independent of the land 1233. The land 1233, the semiconductor device 1210, or the like are formed into a package by a mold resin 1231, such that a portion of the gate lead 1232g, a portion of the drain lead 1232d, and a portion of the source lead 1232s protrude from the package.

Such a discrete package may be manufactured in the following manner, for example.

First, the semiconductor device 1210 is fixed to the land 1233 of a lead frame using the die attach adhesive 1234, such as solder. Next, the gate pad 1226g is connected to the gate lead 1232g of the lead frame, the drain pad 1226d is connected to the drain lead 1232d of the lead frame, and the source pad 1225s is connected to the source lead 1232s of the lead frame, by bonding using the wires 1235g, 1235d and 1235s, respectively. Thereafter, sealing using the mold resin 1231 is performed by transfer molding. The lead frame is then disconnected from the package.

(Sixth embodiment)

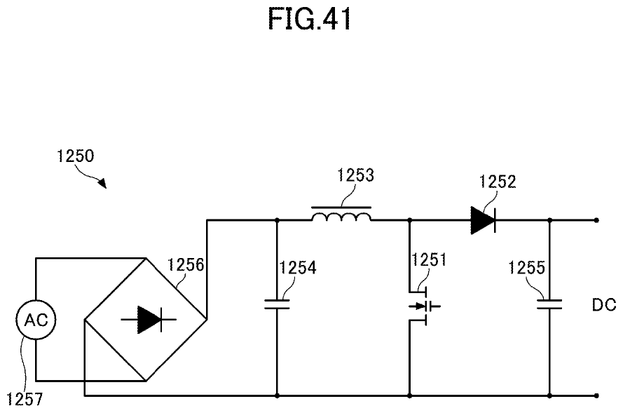

Next, a sixth embodiment will be described. The sixth embodiment relates to a Power Factor Correction (PFC) circuit including the HEMT. FIG. 41 is a circuit diagram illustrating the PFC circuit according to the sixth embodiment.

A PFC circuit 1250 includes a switching device (transistor) 1251, a diode 1252, a choke coil 1253, capacitors 1254 and 1255, a diode bridge 1256, and an AC power supply 1257. A drain electrode of the switching device 1251 is connected to an anode terminal of the diode 1252 and to one terminal of the choke coil 1253. A source electrode of the switching device 1251 is connected to one terminal of the capacitor 1254 and to one terminal of the capacitor 1255. The other terminal of the capacitor 1254 is connected to the other terminal of the choke coil 1253. The other terminal of the capacitor 1255 is connected to the cathode terminal of the diode 1252. In addition, a gate driver is connected to a gate electrode of the switching device 1251. The AC power supply 1257 is connected between the terminals of the capacitor 1254, via the diode bridge 1256. A DC power supply is connected between the terminals of the capacitor 1255. In this embodiment, the switching device 1251 is provided with a semiconductor device having a structure substantially the same as the structure of any one of the first to fourth embodiments.

When manufacturing the PFC circuit 1250, the switching device 1251 is connected to the diode 1252, the choke coil 1253, or the like, using a solder or the like, for example.

(Seventh embodiment)

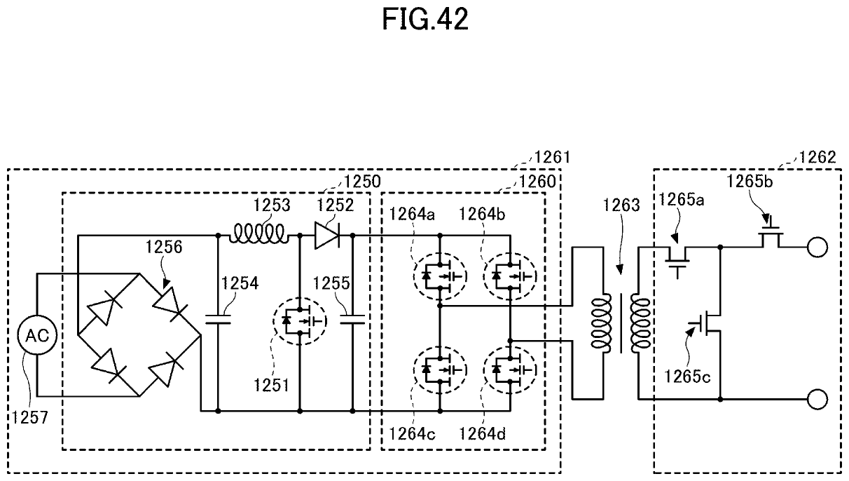

Next, a seventh embodiment will be described. The seventh embodiment relates to a power supply device including the HEMT suitable for use as a server power supply. FIG. 42 is a circuit diagram illustrating a power supply device according to the seventh embodiment.

The power supply includes a high-voltage primary circuit 1261, a low-voltage secondary circuit 1262, and a transformer 1263 disposed between the primary circuit 1261 and the secondary circuit 1262.

The primary circuit 1261 includes the PFC circuit 1250 according to the sixth embodiment, and an inverter circuit, such as a full bridge inverter circuit 1260, connected between the terminals of the capacitor 1255 of the PFC circuit 1250. The full bridge inverter circuit 1260 includes a plurality of (four in this example) switching devices 1264a, 1264b, 1264c, and 1264d.

The secondary circuit 1262 includes a plurality of (three in this example) switching devices 1265a, 1265b, and 1265c.

In this embodiment, a semiconductor device having a structure substantially the same as the structure of any one of the first to fourth embodiments is used for each of the switching device 1251 of the PFC circuit 1250, forming the primary circuit 1261, and the switching devices 1264a, 1264b, 1264c, and 1264d of the full bridge inverter circuit 1260. Conversely, existing MIS type field effect transistors (FETs) using silicon are used for each of the switching devices 1265a, 1265b, and 1265c of the secondary circuit 1262.

(Eighth Embodiment)

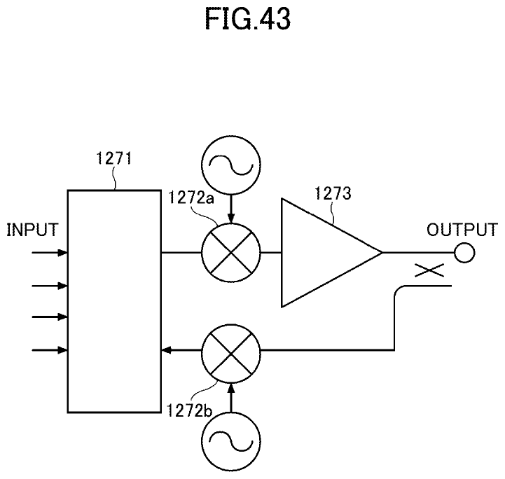

Next, an eighth embodiment will be described. The eighth embodiment relates to an amplifier including the HEMT. FIG. 43 is a circuit diagram illustrating the amplifier according to the eighth embodiment.

The amplifier includes a digital predistortion circuit 1271, mixers 1272a and 1272b, and a power amplifier 1273.

The digital predistortion circuit 1271 compensates for a nonlinear distortion of an input signal. Mixer 1272a mixes the non-linear distortion compensated input signal. The power amplifier 1273 includes a semiconductor device having a similar structure to any of the first to fourth embodiments to amplify the input signal that is mixed with the AC signal. In this embodiment, an output signal can be mixed with the AC signal by the mixer 1272b, and a mixed signal can be transmitted to the digital predistortion circuit 1271, by the switching of switching devices, for example. The amplifier may be used as a high-frequency amplifier or a high-power amplifier. The high-frequency amplifier may be used in transmitters and receivers for cellular base stations, radar devices, and microwave generators, for example.

According to the present disclosures, excellent heat dissipation efficiency can be obtained without forming a thick diamond layer.

Although the preferred embodiment has been described in detail above, various modifications and substitutions can be made to the above-described embodiment without departing from the scope of the claims.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment(s) of the present inventions have been described in detail, it should be understood that the various changes, substitutions, and alterations could be made hereto without departing from the spirit and scope of the invention.

What is claimed is:

1. A semiconductor device comprising:
a substrate having a first surface and a second surface, the second surface being opposite to the first surface, the substrate having an opening formed from the first surface toward the second surface;
a semiconductor device layer having a third surface facing the second surface; and
a heat transfer member disposed in the opening, the heat transfer member being configured to transfer heat generated by the semiconductor device layer to the first surface, wherein the heat transfer member includes a diamond layer and a metal layer, the diamond layer covering a bottom surface and an inner wall surface of the opening, and the metal layer being disposed on the diamond layer.

2. The semiconductor device as claimed in claim 1, wherein the opening extends to the second surface, and the diamond layer is in direct contact with the third surface.

3. The semiconductor device as claimed in claim 1, wherein the diamond layer further covers the first surface.

4. The semiconductor device as claimed in claim 1, further comprising:
a heat sink; and
a connecting member configured to thermally connect the heat sink to the heat transfer member.

5. The semiconductor device as claimed in claim 1, wherein an inner portion of the diamond layer of the opening is filled with the metal layer.

6. The semiconductor device as claimed in claim 1, further comprising:
source electrodes disposed on a fourth surface, the semiconductor device layer having the third surface and the fourth surface, the fourth surface being disposed opposite to the third surface; and
electrically conductive vias penetrating the semiconductor device layer and the diamond layer to electrically connect the source electrodes to the metal layer.

7. The semiconductor device as claimed in claim 1, wherein a thickness of the diamond layer is 5 μm to 10 μm, inclusive. 35

8. The semiconductor device as claimed in claim 1, wherein a thickness of the substrate is 20 μm to 100 μm, inclusive.

9. The semiconductor device as claimed in claim 1, wherein the substrate is an AIN substrate, a SiC substrate, a GaN substrate, or a Si substrate.

10. The semiconductor device as claimed in claim 1, wherein the metal layer includes Cu or Ag.

11. An amplifier comprising the semiconductor device as claimed in claim 1.

12. A power supply device comprising the semiconductor device as claimed in claim 1.

13. A method of manufacturing a semiconductor device, the method comprising:
forming a semiconductor device layer on a substrate, the substrate having a first surface and a second surface opposite to the first surface, the semiconductor device layer having a third surface facing the second surface;
forming an opening from the first surface of the substrate toward the second surface of the substrate; and
forming a heat transfer member in the opening, the heat transfer member being configured to transfer heat generated by the semiconductor device layer to the first surface, wherein the forming of the heat transfer member includes forming of a diamond layer covering a bottom surface and an inner wall surface of the opening, and forming of a metal layer on the diamond layer.
